(19) United States
(12) Patent Application Publication
(10) Pub. No.: US 2006/0270226 A1
(43) Pub. Date: Nov. 30, 2006

(54) Reflective mask blank, reflective mask, and method for manufacturing semiconductor device

(75) Inventor: Morio Hosoya, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: HOYA CORPORATION

(21) Appl. No.: 11/439,145

(22) Filed: May 24, 2006

(30) Foreign Application Priority Data
May 24, 2005 (JP) 2005-150487

(51) Int. Cl. G03F 1/00; H01L 21/44; H01L 23/48

(52) U.S. Cl. 438/686; 430/5; 257/768

(57) ABSTRACT

A reflective mask blank comprises a multilayer reflective film for reflecting exposure light and formed on a substrate, a protective film for protecting the multilayer reflective film and formed above the multilayer reflective film, an absorber film for absorbing the exposure light and formed on the protective film, and a thermal diffusion-preventing film formed between the multilayer reflective film and the protective film. The protective film is made of ruthenium or a ruthenium compound containing ruthenium and at least one selected from the group consisting of molybdenum, niobium, zirconium, yttrium, boron, titanium, and lanthanum. The thermal diffusion-preventing film is made of a material having a refractive index of greater than 0.90 and an extinction coefficient of less than −0.020. A reflective mask comprises the reflective mask blank wherein the absorber film is formed with a pattern to be transferred to a transfer body.

This application claims priority to prior application JP2005-150487, the disclosure of which is incorporated herein by reference.

### BACKGROUND OF THE INVENTION

The present invention relates to a reflective mask, used for semiconductor device manufacture or the like, for exposure; a reflective mask blank for manufacturing the reflective mask; and a method for manufacturing a semiconductor device using the reflective mask,

In the semiconductor industry, an exposure technique using extreme ultraviolet (hereinafter referred to as EUV) light has been recently attracting much attention because the demand for smaller semiconductor devices has increased. The exposure technique is referred to as EUV lithography. EUV light has wavelengths in the soft X-ray or vacuum ultraviolet region and particularly has a wavelength of about 0.2 to 100 nm. Examples of a mask used for EUV lithography includes a reflective mask, disclosed in Japanese Examined Patent Application Publication No. 7-27198 (hereinafter referred to as Patent Document 1), for exposure.

The reflective mask includes a multilayer reflective film, formed on a substrate, for reflecting exposure light and a pattern-like absorber film, formed on the multilayer reflective film, for absorbing exposure light. Light incident on the reflective mask, which is mounted on an exposure system (or a pattern transfer system), is absorbed by the absorber film or reflected by portions of the multilayer reflective film that are exposed from the absorber film, whereby an optical image is transferred to a semiconductor wafer through a reflective optical system.

The multilayer reflective film includes 40 to 60 pairs of molybdenum (Mo) films and silicon (Si) films so as to reflect EUV light with a wavelength of, for example, 13 to 14 nm. The molybdenum and silicon films are alternately stacked and have a thickness of several nanometers. In order to enhance the reflectivity, one of the molybdenum films is preferably placed uppermost because the molybdenum film has a large refractive index. However, molybdenum is readily oxidized by air. This leads to a reduction in reflectivity. Therefore, one of the silicon films is placed uppermost so as to protect the top one of the molybdenum films from being oxidized.

Japanese Unexamined Patent application Publication No. 2002-122981 (hereinafter referred to as Patent Document 2) discloses a reflective mask including a multilayer reflective film including molybdenum films and silicon films alternately stacked, an absorber pattern, and a ruthenium (Ru) buffer layer, formed between the multilayer reflective film and the absorber pattern, for preventing the multilayer reflective film from being damaged due to etching during the formation of the absorber pattern.

In the reflective mask disclosed in Patent Document 1, if the uppermost silicon film serving as a protector has a small thickness, oxidation cannot be prevented. Hence, the uppermost silicon film is formed so as to have a thickness sufficient to prevent oxidation. Since the uppermost silicon film slightly absorbs EUV light, there is a problem in that an increase in the thickness of the uppermost silicon film causes a reduction in the reflectivity of the reflective mask.

In the reflective mask disclosed in Patent Document 2, the ruthenium buffer layer has a problem below.

Ruthenium in the ruthenium buffer layer readily reacts with silicon in the uppermost silicon film to create a diffusion layer during the formation of the ruthenium buffer layer. The creation of the diffusion layer causes a reduction in reflectivity. The diffusion layer is enlarged or grown in a step of forming a protective film and/or a subsequent heating step such as a step of heating the multilayer reflective film to reduce the stress therein, a step of pre-baking a resist film, an exposure step, or a cleaning step. This causes a further reduction in reflectivity. Therefore, the uppermost silicon film has a thickness different from that of the other silicon films such that the reflectivity of the multilayer reflective film is prevented from being decreased due to the diffusion layer.

The inventors have discovered that the use of a ruthenium compound film containing ruthenium and another element such as niobium (Nb) or zirconium (Zr) is more effective in preventing the creation of the diffusion layer as compared to the use of a ruthenium film but ineffective in preventing the creation thereof depending on heat-treating conditions in some cases and the creation thereof causes a reduction in reflectivity. The uppermost silicon film may have a thickness greater than that of the other silicon films such that high reflectivity can be achieved even if the diffusion layer is created.

### SUMMARY OF THE INVENTION

It is a first object of the present invention to provide a reflective mask and a reflective mask blank of which the reflectivity is prevented from being reduced in a step of forming a protective film and/or a subsequent heating step and which has high heat resistance.

It is a second object of the present invention to provide a method for manufacturing a semiconductor device in such a manner that a fine pattern is formed on a wafer by lithography using such a reflective mask.

In order to achieve the above objects, the present invention provides a mask blank, a mask, and a method described below.

(Aspect 1)

A reflective mask blank comprises a substrate, a multilayer reflective film, formed on the substrate, for reflecting exposure light, a protective film, formed above the multilayer reflective film, for protecting the multilayer reflective film, and an absorber film, formed on the protective film, for absorbing the exposure light. The protective film is made of ruthenium or a ruthenium compound containing ruthenium and at least one selected from the group consisting of molybdenum, niobium, zirconium, yttrium, boron, titanium, and lanthanum. The reflective mask blank further comprises a thermal diffusion-preventing film formed between the multilayer reflective film and the protective film. The thermal diffusion-preventing film is made of a material having a refractive index of greater than 0.90 and an extinction coefficient of less than −0.020.

In the reflective mask blank according to the aspect 1, the thermal diffusion-preventing film is formed between the multilayer reflective film and the protective film made of ruthenium or a ruthenium compound. This is effective in preventing diffusion layer from being created between the protective film and the uppermost silicon film of the multilayer reflective film in a step of forming the protective film and/or a subsequent heating step such as a step of heating the multilayer reflective film to reduce the stress therein, a step of prebaking a resist film, an exposure step, or a cleaning step. That is, a reduction in reflectivity due to the diffusion layer can be prevented. Furthermore, the presence of the thermal diffusion-preventing film between the protective film and the multilayer reflective film leads to an increase in reflectivity. Therefore, the reflective mask blank has high optical properties, for example, high reflectivity.

(Aspect 2)

In the reflective mask blank according the aspect 1, the thermal diffusion-preventing film is made of at least one metal selected from the group consisting of molybdenum, niobium, zirconium, yttrium, titanium, and lanthanum or a compound containing at least one selected from the group consisting of molybdenum, niobium, zirconium, yttrium, titanium, and lanthanum and at least one selected from the group consisting of oxygen, boron, nitrogen, carbon, and silicon.

Since the thermal diffusion-preventing film is made of one of the materials specified in the aspect 2, the above advantages of the reflective mask blank according to the aspect 1 can be secured.

(Aspect 3)

In the reflective mask blank according to the aspect 1, the thermal diffusion-preventing film is made of carbon or a compound containing carbon and at least one selected from the group consisting of oxygen, boron, nitrogen, and silicon.

Since the thermal diffusion-preventing film is made of one of the materials specified in the aspect 3, the above advantages of the reflective mask blank according to the aspect 1 can be secured.

(Aspect 4)

In the reflective mask blank according to the aspect 1, the thermal diffusion-preventing film is made of a compound containing at least one selected from the group consisting of oxygen, boron, nitrogen, and silicon.

Since the thermal diffusion-preventing film is made of compound specified in the aspect 4, the above advantages of the reflective mask blank according to the aspect 1 can be secured.

(Aspect 5)

In the reflective mask blank according to any one of the aspects 1 to 4, the thermal diffusion-preventing film has a thickness of 0.5 to 2.5 nm.

Since the thermal diffusion-preventing film has an optimized thickness specified in the aspect 5, the reflective mask blank with which the advantages according to the aspect 1 was achieved to the maximum extent is realizable.

(Aspect 6)

In the reflective mask blank according to any one of the aspects 1 to 5, the reflective mask blank further comprises a Cr based buffer layer formed between the protective film and the absorber film, which contains chromium having etching properties different from those of the absorber film.

Since the reflective mask blank includes the Cr based buffer layer as specified in the aspect 6, the multilayer reflective film can be prevented from being damaged due to etching during the formation a pattern in the absorber film and the repair of the pattern. The Cr based buffer layer has high smoothness and the absorber film formed thereon therefore has high smoothness. Hence, the pattern is distinct.

(Aspect 7)

In the reflective mask blank according to any one of the aspects 1 to 6, the multilayer reflective film is heat-treated.

Since the multilayer reflective film is heat-treated as specified in the aspect 7, the following advantages can be achieved depending on heat-treating conditions described below:

(a) The stress in the multilayer reflective film is reduced and therefore the reflective mask blank has high flatness. This is effective in reducing the warpage of the multilayer reflective film during the manufacture of a reflective mask, resulting in an increase in accuracy in transferring a pattern to a semiconductor wafer.

(b) The peak wavelength and reflectivity of the multilayer reflective film can be prevented from being varied due to thermal causes with time, the peak wavelength being defined as a wavelength at which the reflectivity peaks.

Although the multilayer reflective film is heat-treated such that the stress therein is reduced, the reflectivity of the reflective mask blank can be prevented from being reduced due to the creation of the diffusion layer.

(Aspect 8)

A reflective mask comprises the reflective mask blank according to any one of the aspects 1 to 7. The absorber film is formed with a pattern to be transferred to a transfer body.

Since the reflective mask is manufactured using the reflective mask blank specified in any one of the aspects 1 to 7, the reflective mask is stable in quality and has high reflectivity because the reflectivity of the multilayer reflective film is prevented from being reduced during the manufacture of the reflective mask.

(Aspect 9)

A method for manufacturing a semiconductor device comprises forming a fine pattern on a semiconductor wafer by lithography using the reflective mask according to the aspect 8.

The semiconductor device can be manufactured in such a manner that the fine pattern is formed on the semiconductor wafer by lithography using the reflective mask specified in the aspect 8.

### BRIEF DESCRIPTION OF THE DRAWINGS

FIGS. 1A to 1D are sectional views showing steps of manufacturing a reflective mask blank according to an embodiment of the present invention and steps of manufacturing a reflective mask according to an embodiment of the present invention using the reflective mask blank;

FIG. 2 is a schematic view of a pattern transfer system mounting a reflective mask;

FIG. 3 is a graph showing the relationship between the reflectivity of a reflective mask including an RuNb protective film and the thickness of the RuNb protective film;

FIG. 4 is a graph showing the relationship between the reflectivity of a reflective mask according to a first embodiment of the present invention and the thickness of a thermal diffusion-preventing film, made of different materials, included in the reflective mask;

FIG. 5 is a graph showing the relationship between the reflectivity of a reflective mask according to a second embodiment of the present invention and the thickness of a thermal diffusion-preventing film, made of different materials, included in the reflective mask;

FIG. 6 is a graph showing the relationship between the reflectivity of the reflective mask according to the second embodiment of the present invention and the thickness of the thermal diffusion-preventing film, made of different materials, included in the reflective mask;

FIG. 7 is a graph showing the relationship between the reflectivity of a reflective mask according to a third embodiment of the present invention and the thickness of a thermal diffusion-preventing film, made of different materials, included in the reflective mask;

FIG. 8 is a graph showing the relationship between the reflectivity of the reflective mask according to the third embodiment of the present invention and the thickness of the thermal diffusion-preventing film, made of different materials, included in the reflective mask;

FIG. 9 is a graph showing the relationship between the reflectivity of a reflective mask according to a fourth embodiment of the present invention and the thickness of a thermal diffusion-preventing film, made of different materials, included in the reflective mask;

FIG. 10 is a graph showing the relationship between the reflectivity of the reflective mask according to the fourth embodiment of the present invention and the thickness of the thermal diffusion-preventing film, made of different materials, included in the reflective mask;

FIG. 11 is a graph showing the relationship between the reflectivity of a reflective mask according to a fifth embodiment of the present invention and the thickness of a thermal diffusion-preventing film, made of different materials, included in the reflective mask;

FIG. 12 is a graph showing the relationship between the reflectivity of a reflective mask including an RuZr protective film and the thickness of the RuZr protective film;

FIG. 13 is a graph showing the relationship between the reflectivity of a reflective mask according to a sixth embodiment of the present invention and the thickness of a thermal diffusion-preventing film, made of different materials, included in the reflective mask;

FIG. 14 is a graph showing the relationship between the reflectivity of the reflective mask according to the sixth embodiment of the present invention and the thickness of the thermal diffusion-preventing film, made of different materials, included in the reflective mask;

FIG. 15 is a graph showing the relationship between the reflectivity of the reflective mask according to the sixth embodiment of the present invention and the thickness of the thermal diffusion-preventing film, made of different materials, included in the reflective mask;

FIG. 16 is a graph showing the relationship between the reflectivity of a reflective mask including an RuMo protective film and the thickness of the RuMo protective film;

FIG. 17 is a graph showing the relationship between the reflectivity of a reflective mask according to a seventh embodiment of the present invention and the thickness of a thermal diffusion-preventing film, made of different materials, included in the reflective mask; and

FIG. 18 is a graph showing the relationship between the reflectivity of the reflective mask according to the seventh embodiment of the present invention and the thickness of the thermal diffusion-preventing film, made of different materials, included in the reflective mask.

### DESCRIPTION OF THE PREFERRED EMBODIMENTS

Embodiments of the present invention will now be described in detail.

A reflective mask blank according to the present invention comprises a substrate, a multilayer reflective film, formed on the substrate, for reflecting exposure light, a protective film, formed above the multilayer reflective film, for protecting the multilayer reflective film, and an absorber film, formed on the protective film, for absorbing the exposure light. The protective film is made of ruthenium (Ru) or a ruthenium compound containing ruthenium and at least one selected from the group consisting of molybdenum (Mo), niobium (Nb), zirconium (Zr), yttrium (Y), boron (B), titanium (Ti), and lanthanum (La). A thermal diffusion-preventing film is formed between the multilayer reflective film and the protective film. The thermal diffusion-preventing film is made of a material having a refractive index (n) of greater than 0.90 and an extinction coefficient (k) of less than −0.020.

In the reflective mask blank according to the present invention, the thermal diffusion-preventing film is formed between the multilayer reflective film and the protective film made of ruthenium or a ruthenium compound. This is effective in preventing diffusion layer from being created between the protective film and the uppermost silicon film of the multilayer reflective film in a step of forming the protective film and/or a subsequent heating step such as a step of heating the multilayer reflective film to reduce the stress therein, a step of prebaking a resist film, an exposure step, or a cleaning step. That is, a reduction in reflectivity due to the diffusion layer can be prevented. Furthermore, the presence of the thermal diffusion-preventing film between the protective film and the multilayer reflective film leads to an increase in reflectivity. Therefore, the reflective mask blank has high optical properties, for example, high reflectivity and it is possible to maintain high reflectivity in a reflective region in the reflective mask manufactured from the reflective mask blank because the reduction in reflectivity caused by the heating step no occurs.

The thermal diffusion-preventing film is made of the material having a refractive index (n) of greater than 0.90 and an extinction coefficient (k) of less than −0.020. The material is useful in enhancing optical properties of the thermal diffusion-preventing film, particularly the reflectivity thereof, and useful in preventing the creation of the diffusion layer. Examples of the material include compounds and elements below.

At first, the material of the thermal diffusion-preventing film is at least one metal selected from the group consisting of molybdenum, niobium, zirconium, yttrium, titanium, and lanthanum or a compound containing at least one selected from the group consisting of molybdenum, niobium, zirconium, yttrium, titanium, and lanthanum and at least one selected from the group consisting of oxygen (O), boron (B), nitrogen (N), carbon (C), and silicon (Si). Typical examples of the material include compounds such as Mo₂C, MoC, MoSi₂, NbN, ZrC, ZrN, ZrO₂, Y₂O₃, La₂O₃, LaB₆, TiC, TiN, and TiO₂ and elements such as molybdenum, niobium, zirconium, yttrium, titanium, and lanthanum. If the thermal diffusion-preventing film is made of at least one of these compounds and elements, the reflective mask blank and the reflective mask securely have the above advantages.

Second, the material of the thermal diffusion-preventing film is carbon or a compound containing carbon and at least one selected from the group consisting of oxygen, boron, nitrogen, and silicon. Other typical examples of the material include carbon and compounds such as B₄C and SiC. If the thermal diffusion-preventing film is made of carbon or at least one of these compounds, the reflective mask blank and the reflective mask securely have the above advantages.

Third, the material of the thermal diffusion-preventing film is a compound containing at least one selected from the group consisting of oxygen, boron, nitrogen, and silicon. Other typical examples of the material include compounds such as SiO₂, SiON, BN, and Si₃N₄. If the thermal diffusion-preventing film is made of at least one of these compounds, the reflective mask blank and the reflective mask securely have the above advantages.

The thermal diffusion-preventing film preferably has a thickness of 0.5 to 2.5 nm. The thickness of the thermal diffusion-preventing film depends on the type of the material and is preferably a thickness of 0.5 to 2.0 nm in view of improvement of the reflectivity. If the thickness of the thermal diffusion-preventing film is as described above, the reflective mask blank and the reflective mask securely have the above advantages.

The thermal diffusion-preventing film need not be necessarily uniform in composition and may have a composition gradient such that the composition of the thermal diffusion-preventing film is varied in, for example, the thickness direction. When the thermal diffusion-preventing film has such a composition gradient, the content of an element in the thermal diffusion-preventing film may be varied continuously or stepwise.

The protective film included in the reflective mask blank according to the present invention is made of ruthenium or a ruthenium compound, of which examples can be categorized into three groups below.

A first group includes ruthenium compounds containing ruthenium and at least one of molybdenum and niobium. Typical examples of these ruthenium compounds include Mo₆₃Ru₃₇ and NbRu. When the protective film is made of any one of these compounds, advantages A to D below can be obtained.

A. The protective film has a reflectivity greater than that of a ruthenium film or the uppermost silicon film, included in the multilayer reflective film, serving as capping layer.

B. Since the protective film is resistant to etching under conditions for dry-etching a Cr based buffer layer using an oxygen-containing gas, the multilayer reflective film is protected from being damaged. Hence, the reflectivity can be prevented from being decreased.

C. Since the protective film is also resistant to etching under conditions for dryetching a Ta system absorber film using no oxygen, the multilayer reflective film is protected from being damaged. Hence, the reflectivity can be prevented from being decreased.

D. Since the optimum thickness range of the protective film having high reflectivity is wider than that of the ruthenium film or the silicon film, the initial thickness of the protective film can be set to a relatively large value such that the protective film can resist etching for a long time and the thickness of the etched protective film can be kept in an optimum range even if the thickness of the protective film is unevenly reduced due to etching during the patterning of the absorber film and the Cr based buffer layer formed on the protective film. Hence, it can be protected from being damaged during the etching of the absorber film and the Cr based buffer layer for a long time and therefore can be prevented from being reduced in reflectivity.

A second group includes ruthenium compounds containing ruthenium and at least one of zirconium and yttrium. Typical examples of these ruthenium compounds include ZrRu, Ru₂Y, and Ru₂₅Y₄₄. When the protective film is made of any one of these ruthenium compounds, advantages B to D below can be obtained.

B. Since the protective film is resistant to etching under conditions for dry-etching a Cr based buffer layer using an oxygen containing gas, the multilayer reflective film is protected from being damaged. Hence, the reflectivity can be prevented from being decreased.

C. Since the protective film is also resistant to etching under conditions for dry-etching a Ta system absorber film using no oxygen, the multilayer reflective film is protected from being damaged. Hence, the reflectivity can be prevented from being decreased.

D. Since the optimum thickness range of the protective film having high reflectivity is wider than that of the ruthenium film or the silicon film, the initial thickness of the protective film can be set to a relatively large value such that the protective film can resist etching for a long time and the thickness of the etched protective film can be kept in an optimum range even if the thickness of the protective film is unevenly reduced due to etching during the patterning of the absorber film and the Cr based buffer layer formed on the protective film. Hence, it can be protected from being damaged during the etching of the absorber film and the Cr based buffer layer for a long time and therefore can be prevented from being reduced in reflectivity.

A third group includes ruthenium compounds containing ruthenium and at least one selected from the group consisting of boron, titanium, and lanthanum. Typical examples of these ruthenium compounds include Ru₇B₃, RuB, Ru₂B₃, RuB₂, TiRu, and LaRu₂. When the protective film is made of any one of these ruthenium compounds, advantages B and C below can be obtained.

B. Since the protective film is resistant to etching under conditions for dryetching a Cr based buffer layer using an oxygen-containing gas, the multilayer reflective film is protected from being damaged. Hence, the reflectivity can be prevented from being decreased.

C. Since the protective film is also resistant to etching under conditions for dry-etching a Ta system absorber film using no oxygen, the multilayer reflective film is protected from being damaged. Hence, the reflectivity can be prevented from being decreased.

In order to secure the above advantages, the content of ruthenium in each ruthenium compound included in the groups is preferably 10 to 95 atomic percent. In particular, in order to secure advantage A (in order to enhance the reflectivity), the ruthenium content is more preferably 30 to 95 atomic percent.

In order to secure advantage B (in order to enhance the etching resistance of the protective film), the protective film preferably contains nitrogen. This leads to a reduction in the stress in the protective film and an increase in adhesion between the protective film and the thermal diffusion-preventing film, the absorber film, and/or the buffer layer. The protective film preferably has a nitrogen content of 2 to 30 atomic percent and more preferably 5 to 15 atomic percent.

Furthermore, the protective film may contain carbon or oxygen. When the protective film contains carbon, the protective film has high chemical resistance. When the protective film contains oxygen, the advantage B (the enhancement of the etching resistance of the protective film) can be secured.

The ruthenium compounds, any one of which may be contained in the protective film, contain at least one selected from the group consisting of ruthenium, molybdenum, niobium, zirconium, yttrium, boron, titanium, and lanthanum as described above. The ruthenium compounds may contain two or more of these elements. Examples of this type of ruthenium compound include YRuB₂, (MoRu)₃B₄, and B₆Nb_{3.1}Ru_{19.9}.

The protective film preferably has a thickness of 0.5 to 5 nm. The protective film more preferably has such a thickness that the reflectivity of the multilayer reflective film is maximized.

When the protective film is made of any one of the ruthenium compounds, the protective film need not be necessarily uniform in composition and may have a composition gradient such that the composition of the protective film is varied in, for example, the thickness direction. When the protective film has such a composition gradient, the content of an element in the protective film may be varied continuously or stepwise.

The multilayer reflective film is preferably heat-treated. The heat treatment of the multilayer reflective film provides advantages below depending on heat-treating conditions.

I. The stress in the multilayer reflective film is reduced and therefore the reflective mask blank has high flatness. This is effective in reducing the warpage of the multilayer reflective film during the manufacture of a reflective mask, resulting in an increase in accuracy in transferring a pattern to a semiconductor wafer.

II. The peak wavelength and reflectivity of the multilayer reflective film can be prevented from being varied due to thermal causes with time.

The temperature for heat-treating the multilayer reflective film is preferably 50° C. or more. In order to secure the advantage I, the heat-treating temperature preferably is 50° C. to 150° C. In order to secure the advantage II, the heat-treating temperature preferably is 50° C. to 100° C.

Even if the multilayer reflective film is heat-treated such that the stress therein is reduced, the reflectivity thereof can be prevented from being reduced due to the diffusion layer.

The Cr based buffer layer containing chromium which has etching properties different from those of the absorber film may be formed between the protective film and the absorber film. This prevents the multilayer reflective film from being damaged due to etching during the patterning of the absorber film or during the modification of the resulting pattern. The Cr based buffer layer has high flatness and therefore the absorber film formed thereon has also high flatness. Hence, the pattern is distinct.

A material for forming the Cr based buffer layer may be chromium or may contain chromium and at least one selected from the group consisting of nitrogen, oxygen, carbon, and fluorine. The presence of nitrogen in the Cr based buffer layer increases the flatness thereof, the presence of carbon therein increases the etching resistance thereof, and the presence of oxygen therein reduces the stress therein. Examples of this material include CrN, CrO, CrC, CrF, CrON, CrCO, and CrCON.

The reflective mask blank may have a resist film for forming a predetermined transfer pattern on the absorber film.

The reflective mask prepared by processing the reflective mask blank may have any one of configurations below.

1. The multilayer reflective film, the thermal diffusion-preventing film, the protective film, the buffer layer, and the absorber film pattern having the predetermined transfer pattern are formed on the substrate in that order.

2. The multilayer reflective film, the thermal diffusion-preventing film, the protective film, the buffer layer having the predetermined transfer pattern, and the absorber film pattern are formed on the substrate in that order.

3. The multilayer reflective film, the thermal diffusion-preventing film, the protective film, and the absorber film pattern having the predetermined transfer pattern are formed on the substrate in that order.

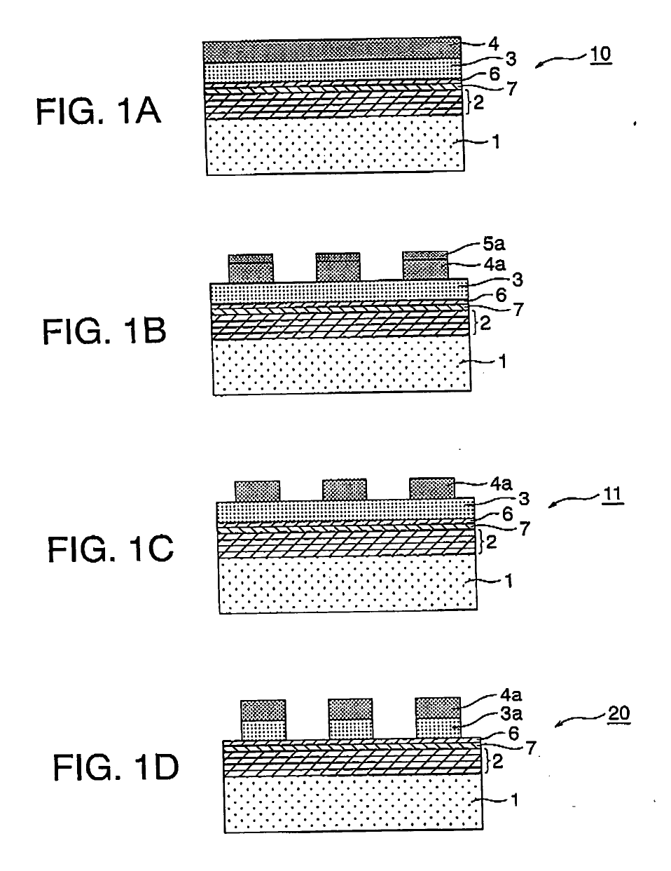

FIGS. 1A to 1D are schematic sectional views showing steps of manufacturing a reflective mask 20 using a reflective mask blank 10 according to an embodiment of the present invention.

With reference to FIG. 1A, the reflective mask blank 10 includes a substrate 1, a multilayer reflective film 2, a thermal diffusion-preventing film 7, a protective film 6, a buffer layer 3, and an absorber film 4, these films and layer being arranged on the substrate 1 in that order.

In order to prevent a pattern from being distorted due to heat during exposure, the substrate 1 preferably has a thermal expansion coefficient of −1.0×10⁻⁷ to 1.0×10⁻⁷ per degree C. and more preferably −0.3×10⁻⁷ to 0.3×10⁻⁷ per degree C. Examples of a material, having such a small thermal expansion coefficient, for forming the substrate 1 include amorphous glass, ceramic, and metal. Examples of amorphous glass include SiO₂—TiO₂ system glass and quartz glass. Alternatively, the substrate 1 may be made of crystallized glass containing a β-quartz solid solution, Invar alloy (Fe—Ni alloy), or single-crystalline silicon.

In order to achieve high reflectivity and transfer accuracy, the substrate 1 preferably has a smooth, flat surface. In particular, the substrate 1 preferably has a surface roughness of 0.2 nm rms or less and a flatness of 100 nm or less, the surface roughness being determined by measuring a 10 μm square area, the flatness being determined by measuring a 142 mm square area. In order to prevent the substrate 1 from being distorted due to the stress in the multilayer reflective film 2, the substrate 1 preferably has high toughness. In particular, the substrate 1 preferably has a Young's modulus of 65 GPa or more.

Rms is an abbreviation for “root mean square” and is used to express surface roughness or the like. Surface roughness can be measured by atomic force microscopy. Flatness refers to surface warpage or distortion shown by total indicated reading (TIR), which is the absolute value of the difference between the highest point of a surface of a wafer and the lowest point of the wafer surface, the highest point being positioned above a focal plane which is determined by the least square method and which is used as a reference plane of the wafer surface, the lowest point being positioned below the focal plane.

The multilayer reflective film 2 has a configuration in which elements having different refractive indexes are periodically stacked as described above or in which first thin films containing a heavy element or a heavy element compound and second thin films containing a light element or a light element compound are alternately stacked in general, the number of pairs of the first and second thin films being 40 to 60.

In order to reflect EUV light with a wavelength of 13 to 14 nm, the multilayer reflective film 2 preferably includes, for example, 40 pairs of molybdenum films and silicon films stacked alternately as a molybdenum/silicon periodic multilayer film. Alternatively, the multilayer reflective film 2 may has a ruthenium/silicon periodic multilayer film, a molybdenum/beryllium periodic multilayer film, a molybdenum compound/silicon compound periodic multilayer film, a silicon/niobium periodic multilayer film, a silicon/molybdenum/ruthenium periodic multilayer film, a silicon/molybdenum/ruthenium/molybdenum periodic multilayer film, or a silicon/ruthenium/molybdenum/ruthenium periodic multilayer film. Materials for forming the multilayer reflective film 2 may be selected depending on the wavelength of exposure light.

The multilayer reflective film 2 can be formed by a DC magnetron sputtering process, an ion beam sputtering process, or another sputtering process. For the molybdenum/silicon multilayer film, the silicon film is formed on the substrate 1 so as to have a thickness of several nanometers using a silicon target and the molybdenum film is then formed on the silicon film so as to have a thickness of several nanometers using a molybdenum target by, for example, the ion beam sputtering process. This pair of the molybdenum and silicon film is referred to as one period. After 40 to 60 pairs of the molybdenum and silicon films are deposited, a silicon film is finally formed on the top molybdenum film. In order to protect this multilayer reflective film 2, the thermal diffusion-preventing film 7 and the protective film 6 which are made of materials according to the present invention are formed on the uppermost silicon film in that order.

The buffer layer 3 preferably has the same configuration as that of the above Cr based buffer layer.

The buffer layer 3 can be formed on the protective film 6 by a sputtering process such as a DC sputtering process, an RF sputtering process, or an ion beam sputtering process.

If a pattern formed in the absorber film 4 is modified using a focused ion beam (FIB), the buffer layer 3 preferably has a thickness of about 20 to 60 nm. If such a pattern is not modified, the buffer layer 3 may have a thickness of about 5 to 15 nm.

The absorber film 4 has a function of absorbing exposure light, for example, EUV light and is therefore preferably made of tantalum or a material principally containing tantalum. Preferable examples of the tantalum-containing material include tantalum alloys. In view of smoothness and flatness, the absorber film 4 is preferably amorphous or polycrystalline.

Other examples of the tantalum-containing material include a material containing tantalum and boron; a material containing tantalum and nitrogen; a material containing tantalum, boron, and at least one of oxygen and nitrogen; a material containing tantalum and silicon; a material containing tantalum, silicon, and nitrogen; a material containing tantalum and germanium; and a material containing tantalum, germanium, and nitrogen. A combination of tantalum and boron, silicon, or germanium is effective in obtaining an amorphous material. This leads to an enhancement in smoothness. A combination of tantalum and nitrogen or oxygen is effective in enhancing oxidation resistance. This leads to an enhancement in long-term stability.

Among the above materials, the material containing tantalum and boron and the material containing tantalum, boron, and nitrogen are preferable. The material containing tantalum and boron preferably has a tantalum to boron ratio ranging from 8.5:1.5 to 7.5:2.5. The content of nitrogen in the material containing tantalum, boron, and nitrogen is preferably 5 to 30 atomic percent and the content of boron in the remainder is preferably 10 to 30 atomic percent. These materials are effective in achieving a polycrystalline or amorphous structure, thereby obtaining good smoothness and flatness.

The absorber film 4 is preferably formed by a sputtering process such as a magnetron sputtering process. When the absorber film 4 contains tantalum, boron, and nitrogen, the absorber film 4 can be formed by such a sputtering process using a target containing tantalum and boron and a gas mixture containing argon and nitrogen. For the sputtering process, the stress in the absorber film 4 can be controlled by varying the electric power applied to the target and/or the pressure of the gas mixture. Furthermore, since the absorber film 4 can be formed at a low temperature close to room temperature, the multilayer reflective film 2 and/or other films can be prevented from being damaged due to heat.

Examples of a material other than the tantalum-containing material include WN, TiN, and Ti.

The absorber film 4 may have a multilayer structure.

The absorber film 4 may have a thickness sufficient to absorb exposure light, for example, EUV light and preferably has a thickness of about 30 to 100 nm.

As shown in FIGS. 1A to 1D, the reflective mask blank 10 includes the buffer layer 3. However, the reflective mask blank 10 need not include the buffer layer 3 depending on a method for patterning the absorber film 4 or a method for modifying the resulting pattern.

Steps of manufacturing this reflective mask 20 using this reflective mask blank 10 will now be described.

The materials and manufacturing procedures of the layers or films included in this reflective mask blank 10 shown in FIG. 1A are as described above.

A step of forming a predetermined transfer pattern in the absorber film 4 will now be described. The absorber film 4 is coated with a resist for electron beam lithography and then baked. The resist is patterned with an electron beam lithography system and then developed, whereby a resist pattern 5a is formed.

The absorber film 4 is dry-etched using the resist pattern 5a as a mask, whereby an absorber film pattern 4a having the transfer pattern is formed as shown in FIG. 1B. When the absorber film 4 is made of the material principally containing tantalum, gas containing chlorine or fluorine may be used to etch this absorber film 4.

The resist pattern 5a remaining on the absorber film pattern 4a is removed with hot concentrated sulfuric acid, whereby a mask 11 is formed as shown in FIG. 1C.

The absorber film pattern 4a is usually checked against design criteria. DUV light with a wavelength of about 190 to 260 nm is used to inspect the absorber film pattern 4a and is therefore applied to the mask 11 having the absorber film pattern 4a. In the inspection, the contrast between the following components is observed: a light component reflected by the absorber film pattern 4a and another light component reflected by a portion of the buffer layer 3 that is exposed from the absorber film pattern 4a.

The inspection is effective in revealing pinholes (white defects) caused by accidentally removing portions of this absorber film 4 and/or etching failures (black defects) that are unnecessary portions of this absorber film 4 that remain due to insufficient etching. If such pinholes and/or etching failures are detected, they are repaired.

In order to repair the pinholes, a carbon film or the like may be deposited over the pinholes by, for example, FIB (Focused Ion Beam)-assisted deposition. In order to repair the etching failures, the unnecessary portions are removed by FIB irradiation. The buffer layer 3 protects this multilayer reflective film 2 from FIB irradiation.

After the inspection and/or repair of the absorber film pattern 4a is finished, portions of this buffer layer 3 that are exposed from the absorber film pattern 4a are removed such that a buffer layer pattern 3a is formed, whereby the reflective mask 20 is manufactured as shown in FIG. 1D. In this step, if the buffer layer 3 is made of the material principally containing chromium (Cr based material), the buffer layer 3 can be dry-etched with a gas mixture containing chlorine and oxygen. Regions of this multilayer reflective film 2 that reflect exposure light are exposed from the buffer layer pattern 3a. The thermal diffusion-preventing film 7 and the protective film 6 overlie the multilayer reflective film 2. The protective film 6 protects the multilayer reflective film 2 during the dry etching of the buffer layer 3.

If desired reflectivity can be achieved without partly removing the buffer layer 3, the buffer layer 3 need not be processed into the buffer layer pattern 3a but may be allowed to remain on the protective film 6.

The absorber film pattern 4a is finally inspected whether the absorber film pattern 4a has dimensions meeting design specifications. The DUV light described above is used for this inspection.

Although the reflective mask 20 is particularly suitable for EUV light, used for exposure, having a wavelength of about 0.2 to 100 nm, another type of light can be used.

The present invention will now be further described in detail with reference to several examples below.

(First Embodiment)

SiO₂—TiO₂ glass substrates were prepared. The glass substrate has a size of 152 mm square, a thickness of 6.3 mm, a thermal expansion coefficient of 0.2×10⁻⁷ per degree C., and a Young's modulus of 67 GPa. The glass substrate is mechanically polished so as to have a surface roughness of 0.2 nm rms or less and a flatness of 100 nm or less.

Multilayer reflective film is formed on the glass substrate. The multilayer reflective film is a molybdenum/silicon periodic multilayer film suitable for exposure light with a wavelength of 13 to 14 nm. In particular, the multilayer reflective film is formed in such a manner that silicon films with a thickness of 4.2 nm and molybdenum films with a thickness of 2.8 nm were alternately deposited on the glass substrate by an ion beam sputtering process using a silicon target and a molybdenum target, respectively. After 40 pairs of the silicon and molybdenum films were formed, a silicon film with a thickness of 4.2 nm was deposited on the top molybdenum film, Thermal diffusion-preventing film described below is deposited on the uppermost silicon film. At last, the RuNb film with a thickness of 2.5 nm is deposited as the protective film on the thermal diffusion-preventing film using an RuNb target, whereby the substrate with the multilayer reflective film were obtained.

As the thermal diffusion-preventing film having a thickness of 1.0 nm, examples 1-1, 1-2, 1-3, and 1-4 were made of SiC, B₄C, graphite, and diamond-like carbon (DLC) by a DC sputtering process, respectively, whereby four kinds of substrates with the multilayer reflective film were obtained.

The examples 1-1 to 1-4 were measured for reflectivity in such a manner that EUV light with a wavelength of 13.5 nm was applied to the respective multilayer reflective films at an incident angle of 6.0 degrees. The measurement showed that the examples 1-1, 1-2, 1-3, and 1-4 had a reflectivity of 66.6%, 66.4%, 66.3%, and 66.0%, respectively. These multilayer reflective films had a surface roughness of about 0.13 nm rms.

Furthermore, first and second samples were prepared. The first samples had substantially the same configuration as that of any one of the examples 1-1 to 1-4 except that the first samples included no thermal diffusion-preventing films and the RuNb protective films included in the respective first samples were directly formed on the respective uppermost silicon films and had a thickness of 0.5 to 5.0 nm. The second samples had substantially the same configuration as that of any one of the examples 1-1 to 1-4 except that the thermal diffusion-preventing films included in the respective second samples had a thickness of 0.5 to 2.5 nm.

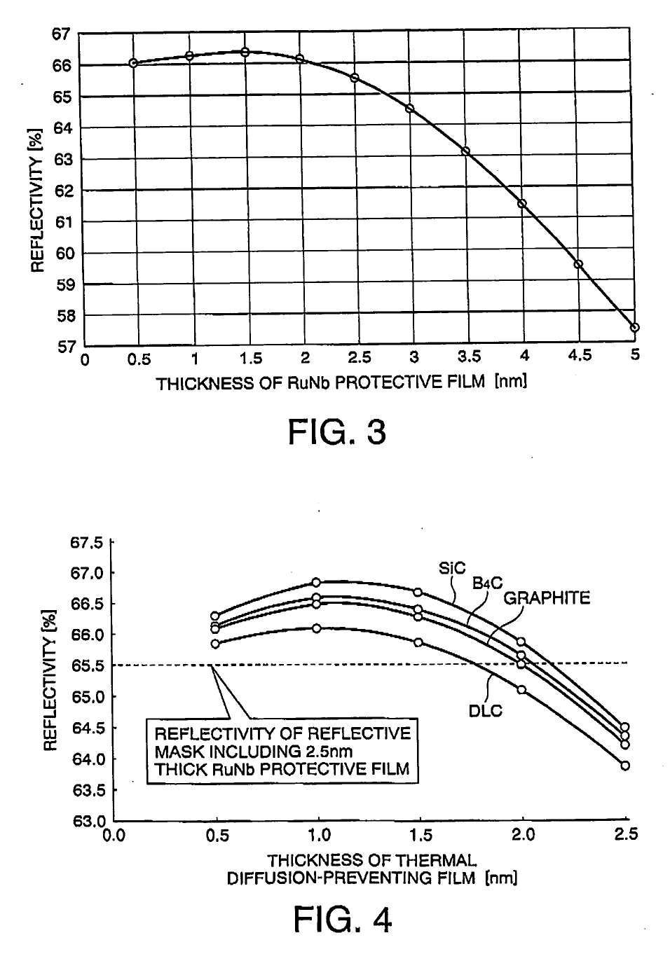

FIG. 3 shows the relationship between the thickness of the RuNb protective film and the reflectivity of one of the first samples.

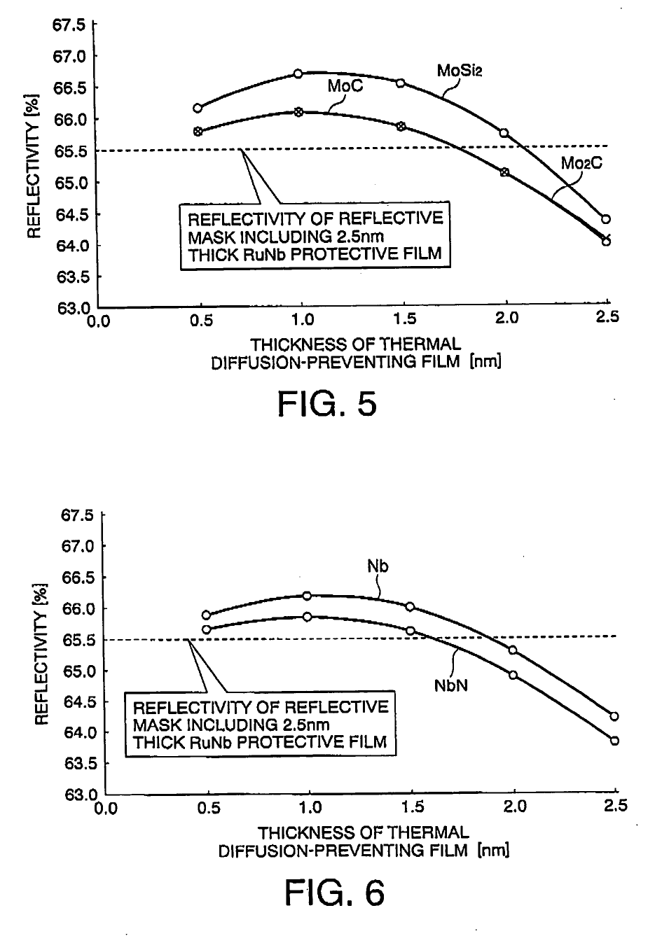

FIG. 4 shows the relationship between the thickness of the thermal diffusion-preventing films of the second samples (four kinds of examples 1-1 to 1-4) and the reflectivity of the second samples. The relationship therebetween may be referred to as the dependency of the reflectivity on the film thickness. The curves shown in FIGS. 3 and 4 were determined by calculation using an optical simulator. The curves shown in FIGS. 5 to 18 described below were determined in the same manner as described above. Practically, the reflectivity of the multilayer reflective films is reduced by about three to four percent in some cases because of the creation of the diffusion layer between the silicon and molybdenum films, the presence of impurities in the silicon and molybdenum films, or another cause. However, the differences in reflectivity between the first and second samples do not depend on the materials of the thermal diffusion-preventing film. The reflectivities shown in FIGS. 3 and 4 can be achieved by reducing the number or size of the diffusion layer and/or the content of the impurities.

As illustrated in FIG. 3, the reflectivity of the first samples sharply decreases with an increase in the thickness of the RuNb protective film in the thickness range exceeding 2.0 nm. The RuNb protective film needs to has a thickness of at least 2.5 nm so as to resist chemicals and/or etching. Hence, the thickness of the RuNb protective film of the examples 1-1 to 1-4 was set to 2.5 nm.

As illustrated in FIG. 4, the second samples including the thermal diffusion-preventing film with a thickness of 0.5 to 2.0 nm have a reflectivity greater than that of one of the first samples that includes the RuNb protective film with a thickness of 2.5 nm. This means that the presence of the thermal diffusion-preventing film between the multilayer reflective film and the protective film leads to an increase in reflectivity. The thermal diffusion-preventing film of the examples 1-1 to 1-4 has such a thickness that the examples 1-1 to 1-4 have a maximum reflectivity. FIG. 4 also illustrates that some of the second samples that include the thermal diffusion-preventing film with a thickness exceeding 2.0 nm have a reflectivity less than that of the first sample including the 2.5 nm thick RuNb protective film depending on the materials of the thermal diffusion-preventing film. However, the presence of the thermal diffusion-preventing film prevents the reflectivity of the second samples from being reduced due to heat treatment. On the other hand, the reflectivity of the first samples is reduced due to heat treatment by several percent because the first samples include no thermal diffusion-preventing film and the diffusion layer is therefore created due to heat treatment. This means that the heat-treated second samples have a reflectivity greater than or equal to that of the heat-treated first sample including the 2.5 nm thick RuNb protective film.

In order to reduce the stress in the multilayer reflective film of the examples 1-1 to 1-4, the examples 1-1 to 1-4 were heat-treated at a substrate temperature of 100° C. for 15 minutes on a hot plate. Resulting examples 1-1 to 1-4 were observed by transmission electron microscopy to investigate the interfaces between the uppermost silicon films and the thermal diffusion-preventing films and the interfaces between the thermal diffusion-preventing films and the protective films. The observation showed that no diffusion layers were present between the above films. There was substantially no difference in reflectivity between heat-treated examples 1-1 to 1-4. The heat-treated examples 1-1 to 1-4 were then allowed to stand for 100 days in air. The inspection of resulting examples 1-1 to 1-4 showed that the reflectivity thereof was hardly varied.

Chromium nitride films were formed as the buffer layers on the RuNb protective films of the examples 1-1 to 1-4 treated as described above so as to have a thickness of 20 nm. In particular, the buffer layers were formed by a DC magnetron sputtering process using a chromium target and a gas mixture containing argon and nitrogen. The buffer layers had a nitrogen content of ten atomic percent, that is, x in a formula Cr₁₋ₓNₓ was equal to 0.1.

Absorber films containing tantalum, boron, and nitrogen were formed on the respective buffer layers by a DC magnetron sputtering process using a target containing tantalum and boron and a gas mixture containing argon and 10% nitrogen so as to have a thickness of 80 nm, whereby reflective mask blanks of the first embodiment were obtained, The absorber films (TaBN films) had a tantalum content of 80 atomic percent, a boron content of 10 atomic percent, and a nitrogen content of 10 atomic percent.

A reflective mask for EUV exposure is prepared using the respective reflective mask blank so as to have a DRAM pattern for 70-nm design rule 16-Gbit DRAMs as described below.

A resist layer for electron beam lithography was formed on the reflective mask blank, processed by electron beam lithography, and then developed, whereby a resist pattern was formed.

The absorber film was dry-etched with chlorine using the resist pattern as a mask, whereby a transfer pattern was formed in the absorber film.

Portions of the buffer layer that were located above reflective regions of the multilayer reflective film were removed according to the transfer pattern by dry etching using a gas mixture containing chlorine and oxygen, the reflective regions being not covered with the transfer pattern, whereby the multilayer reflective film was partly exposed. This provided the reflective mask. In this step, the etching selective ratio of the RuNb protective film to the buffer layer was 25.

The resulting reflective masks were finally inspected. The inspection showed that the reflective masks each had the DRAM pattern, which met design specifications. The reflective masks had high reflectivities close to those of the examples 1-1 to 1-4, the reflectivities of the reflective masks being determined by applying EUV light to the reflective regions.

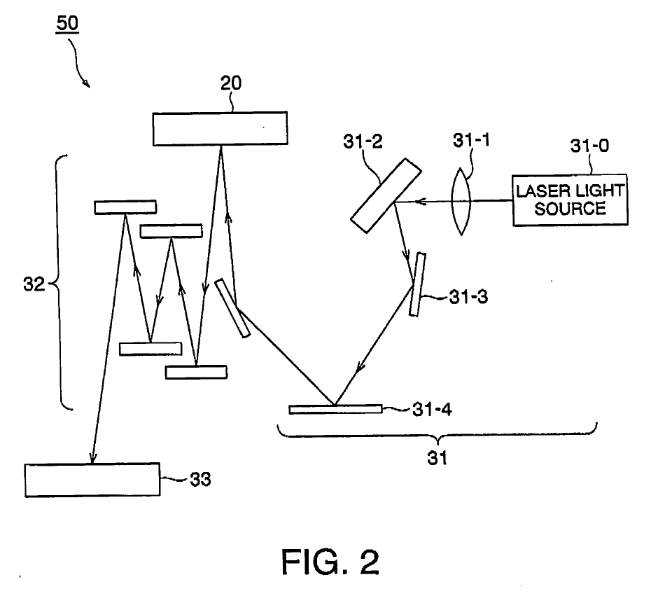

FIG. 2 shows a pattern transfer system 50 including a laser-plasma X-ray source 31 and a demagnification lens unit 32. The laser-plasma X-ray source 31 comprises a laser light source 31-0, a lens 31-1, a target 31-2, and reflective mirrors 31-3 and 31-4. The laser-plasma X-ray source 31 emits EUV light with a wavelength of about 13 to 14 nm. The demagnification lens unit 32 includes X-ray reflective mirrors and has a function of reducing the size of an optical image, obtained from the DRAM pattern of each reflective mask represented by reference numeral 20, to about one fourth. The pattern transfer system 50 further includes a vacuum section through which the EUV light passes.

The reflective mask 20 was attached to the pattern transfer system 50. The DRAM pattern was transferred to a silicon wafer 33 with the pattern transfer system 50 as described below.

The EUV light was emitted from the laser-plasma X-ray source 31 and then applied to the reflective mask 20. Light reflected by the reflective mask 20 was applied to a resist layer formed on the silicon wafer 33 through the demagnification lens unit 32.

The EUV light applied to the reflective mask 20 is partly absorbed by the absorber film pattern 4a shown in FIG. 1D and partly reflected by the reflective regions exposed from the absorber film pattern 4a. The optical light reflected by the reflective mask 20 passes through the demagnification lens unit 32 and then reaches the resist layer, whereby the resist layer of the silicon wafer 33 is exposed. The resulting resist layer was developed, whereby the same pattern as the DRAM pattern was formed on the silicon wafer 33.

The inspection of the resulting silicon wafer 33 showed that the transferred pattern on the silicon wafer 33 had a line width of 16 nm or less, that is, the reflective mask 20 met 70-nm design rule requirements.

(Second Embodiment)

Examples 2-1 to 2-5 were prepared as the substrates with the multilayer reflective film. The examples 2-1 to 2-5 had substantially the same configuration as those of the examples 1-1 to 1-4 except that thermal diffusion-preventing films included in the respective examples 2-1, 2-2, 2-3, 2-4, and 2-5 were made of MoSi₂, MoC, Mo₂C, niobium, or NbN, respectively. The thermal diffusion-preventing films were formed by an ion beam sputtering process so as to have a thickness of 1.0 nm. The examples 2-1 to 2-5 were measured for reflectivity in such a manner that EUV light with a wavelength of 13.5 nm was applied to multilayer reflective film included in the respective examples 2-1 to 2-5 at an incident angle of 6.0 degrees. The measurement showed that the examples 2-1, 2-2, 2-3, 2-4, and 2-5 had a reflectivity of 66.5%, 65.9%, 65.9%, 66.0%, and 65.7%, respectively.

Furthermore, third samples and fourth samples were prepared. The third samples are the same with the examples 2-1 to 2-3 except that the thickness of the thermal diffusion-preventing film. The fourth samples are the same with the examples 2-4 and 2-5 except that the thickness of the thermal diffusion-preventing film.

FIG. 5 shows the relationship between the thickness of the thermal diffusion-preventing films of the third samples and the reflectivity of the third samples.

FIG. 6 shows the relationship between the thickness of the thermal diffusion-preventing films of the fourth samples and the reflectivity of the fourth samples. FIGS. 5 and 6 illustrate that the third and fourth samples including the thermal diffusion-preventing films with a thickness of 0.5 to 2.0 nm have a reflectivity greater than that of the first sample including the 2.5 nm thick RuNb protective film. This means that the presence of the thermal diffusion-preventing film between the multilayer reflective film and the protective film leads to an increase in reflectivity. The thermal diffusion-preventing films of the examples 2-1 to 2-5 have such a thickness that the examples 2-1 to 2-5 have a maximum reflectivity. FIGS. 5 and 6 also illustrate that the third and fourth samples that include the thermal diffusion-preventing films with a thickness exceeding 2.0 nm have a reflectivity less than that of the first sample including the 2.5 nm thick RuNb protective film depending on the materials of the thermal diffusion-preventing films. The presence of the thermal diffusion-preventing films prevents the reflectivity of third and fourth samples from being reduced due to heat treatment. However, the reflectivity of the first samples is reduced due to heat treatment as described in the first embodiment 1. This means that the heat-treated third and fourth samples have a reflectivity greater than or equal to that of the heat-treated first sample including the 2.5 nm thick RuNb protective film.

In order to reduce the stress in the multilayer reflective film of the examples 2-1 to 2-5, the examples 2-1 to 2-5 were heat-treated at a substrate temperature of 100° C. for 15 minutes on a hot plate. Resulting examples 2-1 to 2-5 were observed by transmission electron microscopy to investigate the interfaces between the uppermost silicon films of the multilayer reflective film and the thermal diffusion-preventing film and the interfaces between the thermal diffusion-preventing film and the protective film. The observation showed that no diffusion layers were present between the above layers. There was substantially no difference in reflectivity between heat-treated examples 2-1 to 2-5. The heat-treated examples 2-1 to 2-5 were then allowed to stand for 100 days in air. The inspection of resulting examples 2-1 to 2-5 showed that the reflectivity thereof was hardly varied.

Reflective mask blanks were prepared using the examples 2-1 to 2-5 and reflective masks having DRAM patterns were then prepared using the reflective mask blanks in the same manner as that described in the first embodiment. The reflective mask blanks and the reflective masks were measured for reflectivity using EUV light. The measurement showed that there were no serious differences between the examples 2-1 to 2-5, the reflective mask blanks, and the reflective masks, that is, the reflective mask blanks and the reflective masks had high reflectivity.

The DRAM patterns were transferred to semiconductor wafers with the pattern transfer system 50 shown in FIG. 2. The inspection of the resulting semiconductor wafers showed that the transferred patterns on the semiconductor wafers had a line width of 16 nm or less, that is, the reflective masks met 70-nm design rule requirements.

(Third Embodiment)

Examples 3-1 to 3-6 were prepared. The examples 3-1 to 3-6 had substantially the same configuration as that of the examples 1-1 to 1-4 except that thermal diffusion-preventing films included in respective examples 3-1, 3-2, 3-3, 3-4, 3-5, and 3-6 were made of zirconium, ZrC, ZrN, ZrO₂, yttrium, and Y₂O₃, respectively. The thermal diffusion-preventing films were formed by an ion beam sputtering process so as to have a thickness of 1.0 nm. The examples 3-1 to 3-6 were measured for reflectivity in such a manner that EUV light with a wavelength of 13.5 nm was applied to multilayer reflective films included in the respective examples 3-1 to 3-6 at an incident angle of 6.0 degrees. The measurement showed that the examples 3-1, 3-2, 3-3, 3-4, 3-5, and 3-6 had a reflectivity of 66.3%, 66.2%, 65.9%, 65.8%, 66.6%, and 66.1%, respectively.

Furthermore, fifth samples and sixth samples were prepared. The fifth samples had substantially the same configuration as that of the examples 3-1 to 3-4 except that thermal diffusion-preventing films included in the respective fifth samples had a thickness of 0.5 to 2.5 nm. The sixth samples had substantially the same configuration as that of the examples 3-5 and 3-6 except that thermal diffusion-preventing films included in the respective sixth samples had a thickness of 0.5 to 2.5 nm.

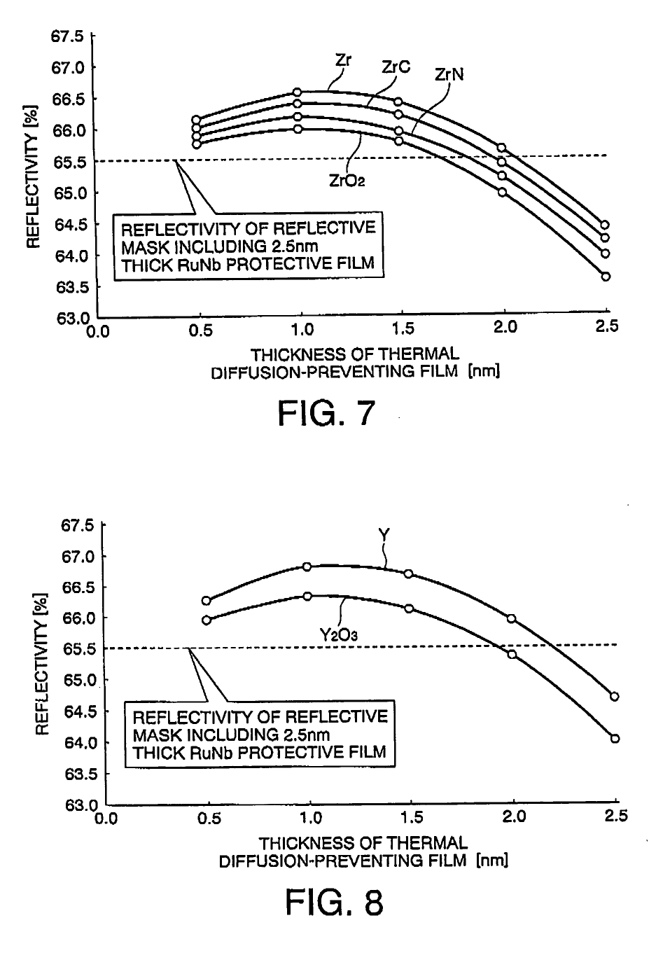

FIG. 7 shows the relationship between the thickness of the thermal diffusion-preventing films of the fifth samples and the reflectivity of the fifth samples.

FIG. 8 shows the relationship between the thickness of the thermal diffusion-preventing films of the sixth samples and the reflectivity of the sixth samples. FIGS. 7 and 8 illustrate that the fifth and sixth samples including the thermal diffusion-preventing films with a thickness of 0.5 to 2.0 nm have a reflectivity greater than that of the first sample including the 2.5 nm thick RuNb protective film.

FIGS. 7 and 8 also illustrate that the fifth and sixth samples that include the thermal diffusion-preventing films with a thickness exceeding 2.0 nm have a reflectivity less than that of the first sample including the 2.5 nm thick RuNb protective film depending on the materials of the thermal diffusion-preventing films. The presence of the thermal diffusion-preventing film prevents the reflectivity of the fifth and sixth samples from being reduced due to heat treatment. However, the reflectivity of the first samples is reduced due to heat treatment as described in the first embodiment. This means that the heat-treated fifth and sixth samples have a reflectivity greater than or equal to that of the heat-treated first sample including the 2.5 nm thick RuNb protective film.

In order to reduce the stress in the multilayer reflective films of the examples 3-1 to 3-6, the examples 3-1 to 3-6 were heat-treated at a substrate temperature of 100° C. for 15 minutes on a hot plate. Resulting examples 3-1 to 3-6 were observed by transmission electron microscopy to investigate the interfaces between the uppermost silicon films of the multilayer reflective films and the thermal diffusion-preventing films and the interfaces between the thermal diffusion-preventing films and the protective films. The observation showed that no diffusion layers were present between the above films. There was substantially no difference in reflectivity between heat-treated examples 3-1 to 3-6. The heat-treated examples 3-1 to 3-6 were then allowed to stand for 100 days in air. The inspection of resulting examples 3-1 to 3-6 showed that the reflectivity thereof was hardly varied.

Reflective mask blanks were prepared using the examples 3-1 to 3-6 and reflective masks having DRAM patterns were then prepared using the reflective mask blanks in the same manner as that described in the first embodiment. The reflective mask blanks and the reflective masks were measured for reflectivity using EUV light. The measurement showed that there were no serious differences between the examples 3-1 to 3-6, the reflective mask blanks, and the reflective masks, that is, the reflective mask blanks and the reflective masks had high reflectivity.

The DRAM patterns were transferred to semiconductor wafers with the pattern transfer system 50 shown in FIG. 2. The inspection of the resulting semiconductor wafers showed that the transferred patterns on the semiconductor wafers had a line width of 16 nm or less, that is, the reflective masks met 70-nm design rule requirements.

(Fourth Embodiment)

Examples 4-1 to 4-6 were prepared. The examples 4-1 to 4-6 had substantially the same configuration as that of the of examples 1-1 to 1-4 except that thermal diffusion-preventing films included in the respective examples 4-1, 4-2, 4-3, 4-4, 4-5, and 4-6 were made of lanthanum, LaB₆, La₂O₃, TiC, TiO₂, and TiN, respectively. The thermal diffusion-preventing films were formed by an ion beam sputtering process so as to have a thickness of 1.0 nm. The examples 4-1 to 4-6 were measured for reflectivity in such a manner that EUV light with a wavelength of 13.5 nm was applied to multilayer reflective films included in the respective examples 4-1 to 4-6 at an incident angle of 6.0 degrees. The measurement showed that the examples 4-1, 4-2, 4-3, 4-4, 4-5, and 4-6 had a reflectivity of 67.0%, 66.8%, 66.4%, 65.7%, 65.6%, and 65.6%, respectively.

Furthermore, seventh samples and eighth samples were prepared. The seventh samples had substantially the same configuration as that of the examples 4-1 to 4-3 except that thermal diffusion-preventing films included in the respective seventh samples had a thickness of 0.5 to 2.5 nm. The eighth samples had substantially the same configuration as that of the examples 4-4 to 4-6 except that thermal diffusion-preventing films included in the respective seventh samples had a thickness of 0.5 to 2.5 nm.

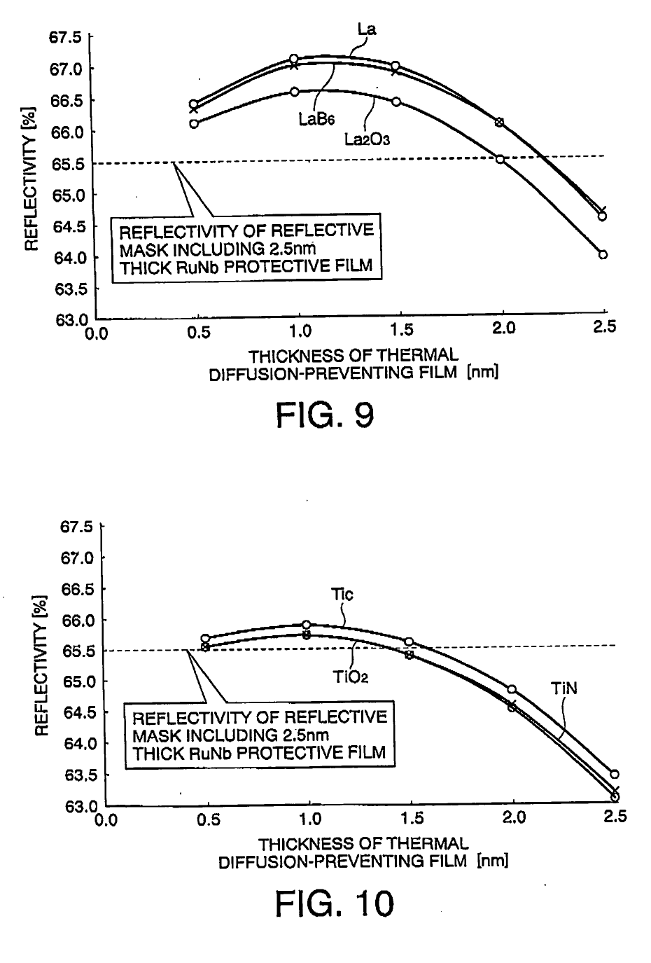

FIG. 9 shows the relationship between the thickness of the thermal diffusion-preventing films of the seventh samples and the reflectivity of the seventh samples.

FIG. 10 shows the relationship between the thickness of the thermal diffusion-preventing films of the eighth samples and the reflectivity of the eighth samples. FIGS. 9 and 10 illustrate that the seventh and eighth samples including the thermal diffusion-preventing films with a thickness of 0.5 to 2.0 nm have a reflectivity greater than that of the first sample including the 2.5 nm thick RuNb protective film.

FIGS. 9 and 10 also illustrate that the seventh and eighth samples that include the thermal diffusion-preventing films with a thickness exceeding 2.0 nm have a reflectivity less than that of the first sample including the 2.5 nm thick RuNb protective film depending on the materials of the thermal diffusion-preventing films. The presence of the thermal diffusion-preventing films prevents the reflectivity of the seventh and eighth samples from being reduced due to heat treatment. However, the reflectivity of the first samples is reduced due to heat treatment as described in the first embodiment. This means that the heat-treated seventh and eighth samples have a reflectivity greater than or equal to that of the heat-treated first sample including the 2.5 nm thick RuNb protective film.

In order to reduce the stress in the multilayer reflective films of the examples 4-1 to 4-6, the examples 4-1 to 4-6 were heat-treated at a substrate temperature of 100° C. for 15 minutes on a hot plate. Resulting examples 4-1 to 4-6 were observed by transmission electron microscopy to investigate the interfaces between the uppermost silicon films of the multilayer reflective films and the thermal diffusion-preventing films and the interfaces between the thermal diffusion-preventing films and the protective films. The observation showed that no diffusion layers were present between the above films. There was substantially no difference in reflectivity between heat-treated examples 4-1 to 4-6. The heat-treated examples 4-1 to 4-6 were then allowed to stand for 100 days in air. The inspection of resulting examples 4-1 to 4-6 showed that the reflectivity thereof was hardly varied.

Reflective mask blanks were prepared using the examples 4-1 to 4-6 and reflective masks having DRAM patterns were then prepared using the reflective mask blanks in the same manner as that described in the first embodiment. The reflective mask blanks and the reflective masks were measured for reflectivity using EUV light. The measurement showed that there were no serious differences between the examples 4-1 to 4-6, the reflective mask blanks, and the reflective masks, that is, the reflective mask blanks and the reflective masks had high reflectivity.

The DRAM patterns were transferred to semiconductor wafers with the pattern transfer system 50 shown in FIG. 2. The inspection of the resulting semiconductor wafers showed that the transferred patterns on the semiconductor wafers had a line width of 16 nm or less, that is, the reflective masks met 70-nm design rule requirements.

(Fifth Embodiment)

Examples 5-1 to 5-4 were prepared. The examples 5-1 to 5-4 had substantially the same configuration as that of the examples 1-1 to 1-4 except that thermal diffusion-preventing films included in the respective examples 5-1, 5-1, 5-3, and 5-4 were made of SiON, Si₃N₄, BN, and SiO₂, respectively. The thermal diffusion-preventing films were formed by an ion beam sputtering process so as to have a thickness of 1.0 nm. The examples 5-1 to 5-4 were measured for reflectivity in such a manner that EUV light with a wavelength of 13.5 nm was applied to multilayer reflective films included in the respective examples 5-1 to 5-4 at an incident angle of 6.0 degrees. The measurement showed that the examples 5-1, 5-2, 5-3, and 5-4 had a reflectivity of 66.6%, 66.5%, 66.3%, and 66.3%, respectively.

Furthermore, ninth samples were prepared. The ninth samples had substantially the same configuration as that of the examples 5-1 to 5-4 except that thermal diffusion-preventing films included in the respective ninth samples had a thickness of 0.5 to 2.5 nm.

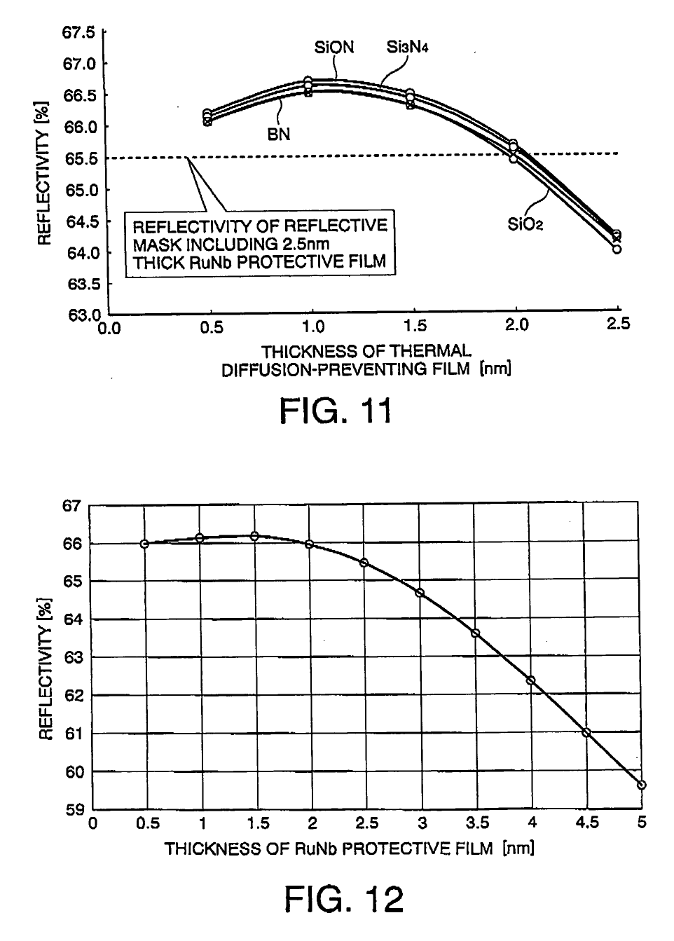

FIG. 11 shows the relationship between the thickness of the thermal diffusion-preventing films of the ninth samples and the reflectivity of the ninth samples. As illustrated in FIG. 11, the ninth samples including the thermal diffusion-preventing films with a thickness of 0.5 to 2.0 nm have a reflectivity greater than that of the first sample including the 2.5 nm thick RuNb protective film.

FIG. 11 also illustrates that the ninth samples that include the thermal diffusion-preventing films with a thickness exceeding 2.0 nm have a reflectivity less than that of the first sample including the 2.5 nm thick RuNb protective film depending on the materials of the thermal diffusion-preventing films. The presence of the thermal diffusion-preventing films prevents the reflectivity of the ninth samples from being reduced due to heat treatment. However, the reflectivity of the first samples is reduced due to heat treatment as described in the first embodiment. This means that the heat-treated ninth samples have a reflectivity greater than or equal to that of the heat-treated first sample including the 2.5 nm thick RuNb protective film.

In order to reduce the stress in the multilayer reflective films of the examples 5-1 to 5-4, the examples 5-1 to 5-4 were heat-treated at a substrate temperature of 100° C. for 15 minutes on a hot plate. Resulting examples 5-1 to 5-4 were observed by transmission electron microscopy to investigate the interfaces between the uppermost silicon films of the multilayer reflective film s and the thermal diffusion-preventing films and the interfaces between the thermal diffusion-preventing films and the protective films. The observation showed that no diffusion layers were present between the above layers. There was substantially no difference in reflectivity between heat-treated examples 5-1 to 5-4. The heat-treated examples 5-1 to 5-4 were then allowed to stand for 100 days in air. The inspection of resulting examples 5-1 to 5-4 showed that the reflectivity thereof was hardly varied.

Reflective mask blanks were prepared using the examples 5-1 to 5-4 and reflective masks having DRAM patterns were then prepared using the reflective mask blanks in the same manner as that described in the first embodiment. The reflective mask blanks and the reflective masks were measured for reflectivity using EUV light. The measurement showed that there were no serious differences between the examples 5-1 to 5-4, the reflective mask blanks, and the reflective masks, that is, the reflective mask blanks and the reflective masks had high reflectivity.

The DRAM patterns were transferred to semiconductor wafers with the pattern transfer system 50 shown in FIG. 2. The inspection of the resulting semiconductor wafers showed that the transferred patterns on the semiconductor wafers had a line width of 16 nm or less, that is, the reflective masks met 70-nm design rule requirements.

(Sixth Embodiment)

Examples 6-1 to 6-10 were prepared. The examples 6-1 to 6-10 had substantially the same configuration as that of the examples 1-1 to 1-4 except that thermal diffusion-preventing films included in respective examples 6-1, 6-2, 6-3, 6-4, 6-5, 6-6, 6-7, 6-8, 6-9, and 6-10 were made of SiC, B₄C, graphite, DLC, MoSi₂, MoC, Mo₂C, ZrC, ZrN, and ZrO₂, respectively, and protective films included in respective examples 6-1 to 6-10 were made of RuZr. The protective films and the thermal diffusion-preventing films were formed by an ion beam sputtering process so as to have a thickness of 2.5 and 1.0 nm, respectively.

The examples 6-1 to 6-10 were measured for reflectivity in such a manner that EUV light with a wavelength of 13.5 nm was applied to multilayer reflective films included in the respective examples 6-1 to 6-10 at an incident angle of 6.0 degrees. The measurement showed that the examples 6-1, 6-2, 6-3, 6-4, 6-5, 6-6, 6-7, 6-8, 6-9, and 6-10 had a reflectivity of 66.6%, 66.4%, 66.3%, 65.9%, 66.5%, 65.8%, 65.8%, 66.2%, 66.0%, and 65.8%, respectively. The multilayer reflective films had a surface roughness of 0.13 nm rms.

Furthermore, tenth to thirteenth samples were prepared. The tenth samples had substantially the same configuration as that of the examples 6-1 to 6-10 except that the tenth samples included no thermal diffusion-preventing films and RuZr protective films included in the respective tenth samples had a thickness of 0.5 to 2.5 nm and were directly formed on the respective uppermost silicon films of multilayer reflective films included in the respective tenth samples. The eleventh samples had substantially the same configuration as that of the examples 6-1 to 6-4 except that thermal diffusion-preventing films included in the respective eleventh samples had a thickness of 0.5 to 2.5 nm. The twelfth samples had substantially the same configuration as that of the examples 6-5 and 6-6 except that thermal diffusion-preventing films included in the respective twelfth samples had a thickness of 0.5 to 2.5 nm. The thirteenth samples had substantially the same configuration as that of the examples 6-8 to 6-10 except that thermal diffusion-preventing films included in the respective thirteenth samples had a thickness of 0.5 to 2.5 nm.

FIG. 12 shows the relationship between the thickness of the RuZr protective films and the reflectivity of the tenth samples.

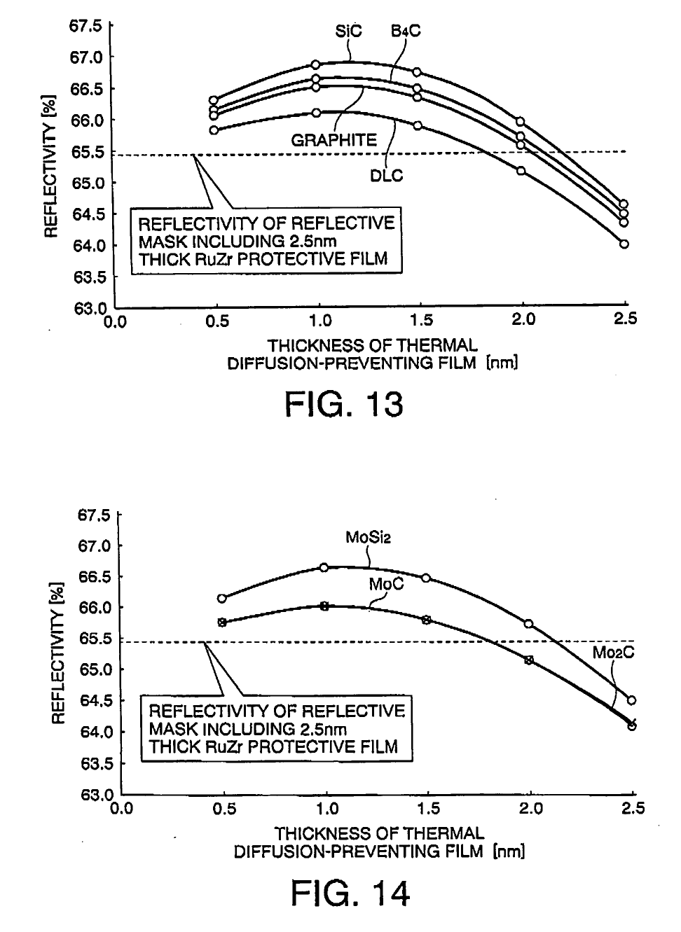

FIG. 13 shows the relationship between the thickness of the thermal diffusion-preventing films of the eleventh samples and the reflectivity of the eleventh samples.

FIG. 14 shows the relationship between the thickness of the thermal diffusion-preventing films of the twelfth samples and the reflectivity of the twelfth samples.

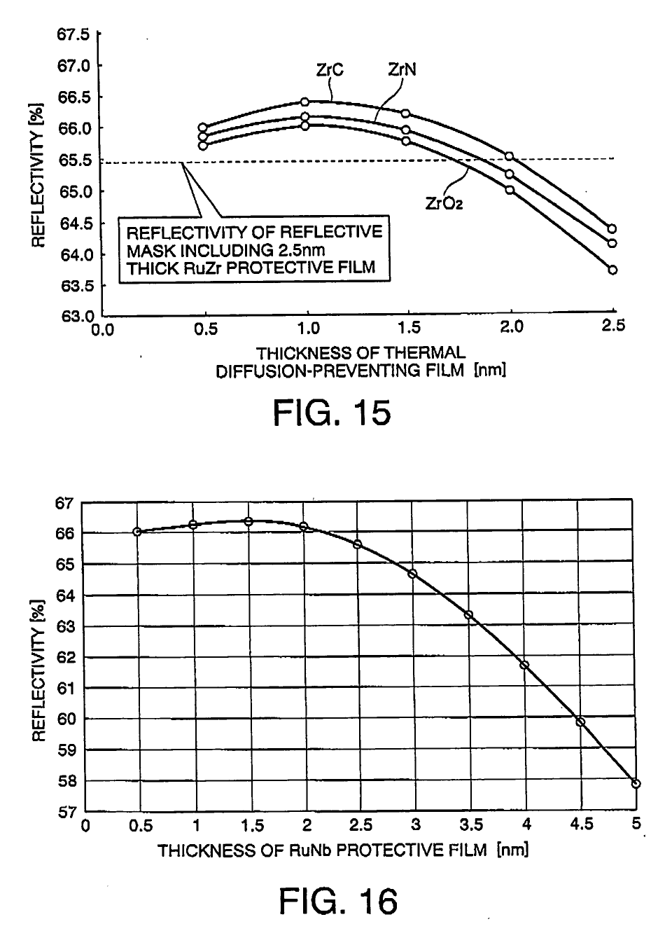

FIG. 15 shows the relationship between the thickness of the thermal diffusion-preventing films of the thirteenth samples and the reflectivity of the thirteenth samples.

As illustrated in FIG. 12, the reflectivity of the tenth samples sharply decreases with an increase in the thickness of the RuZr protective films in the thickness range exceeding 2.0 nm. The RuZr protective films need to have a thickness of at least 2.5 nm so as to resist chemicals and/or etching. Hence, in the sixth embodiment, the thickness of the protective films was set to 2.5 nm.

As illustrated in FIGS. 13 to 15, the eleventh to thirteenth samples including the thermal diffusion-preventing films with a thickness of 0.5 to 2.0 nm have a reflectivity greater than that of the tenth samples that includes the RuZr protective film with a thickness of 2.5 nm. This means that the presence of the thermal diffusion-preventing films between the multilayer reflective films and the protective films leads to an increase in reflectivity. The thermal diffusion-preventing films of the examples 6-1 to 6-10 have such a thickness that the examples 6-1 to 6-10 have a maximum reflectivity. FIGS. 13 to 15 also illustrate that the eleventh to thirteenth samples that include the thermal diffusion-preventing films with a thickness exceeding 2.0 nm have a reflectivity less than that of the tenth sample including the 2.5 nm thick RuZr protective film depending on the materials of the thermal diffusion-preventing films. The presence of the thermal diffusion-preventing films prevents the reflectivity of the eleventh to thirteenth samples from being reduced due to heat treatment. However, the reflectivity of the tenth samples is reduced due to heat treatment by several percent because the tenth samples include no thermal diffusion-preventing films and diffusion layers are therefore created due to heat treatment. This means that the heat-treated eleventh to thirteenth samples have a reflectivity greater than or equal to that of the tenth sample including the 2.5 nm thick RuZr protective film.

In order to reduce the stress in the multilayer reflective films of the examples 6-1 to 6-10, the examples 6-1 to 6-10 were heat-treated at a substrate temperature of 100° C. for 15 minutes on a hot plate. Resulting examples 6-1 to 6-10 were observed by transmission electron microscopy to investigate the interfaces between the uppermost silicon films of the multilayer reflective films and the thermal diffusion-preventing films and the interfaces between the thermal diffusion-preventing films and the protective films. The observation showed that no diffusion layers were present between the above films. There was substantially no difference in reflectivity between the heat-treated examples 6-1 to 6-10. The heat-treated examples 6-1 to 6-10 were then allowed to stand for 100 days in air. The inspection of resulting examples 6-1 to 6-10 showed that the reflectivity thereof was hardly varied.

Reflective mask blanks were prepared using the examples 6-1 to 6-10 and reflective masks having DRAM patterns were then prepared using the reflective mask blanks in the same manner as that described in the first embodiment. The reflective mask blanks and the reflective masks were measured for reflectivity using EUV light. The measurement showed that there were no serious differences between the examples 6-1 to 6-10, the reflective mask blanks, and the reflective masks, that is, the reflective mask blanks and the reflective masks had high reflectivity.

The DRAM patterns were transferred to semiconductor wafers with the pattern transfer system 50 shown in FIG. 2. The inspection of the resulting semiconductor wafers showed that the transferred patterns on the semiconductor wafers had a line width of 16 nm or less, that is, the reflective masks met 70-nm design rule requirements.

(Seventh Embodiment)

Examples 7-1 to 7-7 were prepared. The examples 7-1 to 7-7 had substantially the same configuration as that the examples 1-1 to 1-4 except that thermal diffusion-preventing films included in respective examples 7-1, 7-2, 7-3, and 7-4 were made of SiC, B₄C, graphite, and DLC, respectively, and formed by a DC sputtering process and thermal diffusion-preventing films included in the respective 7-5, 7-6, and 7-7 were made of MoSi₂, MoC, and Mo₂C, respectively, and formed by an ion beam sputtering process.

Protective films included in the respective examples 7-1 to 7-7 were made of RuMo and had a thickness of 2.5 nm. The thermal diffusion-preventing films had a thickness of 1.0 nm.

The examples 7-1 to 7-7 were measured for reflectivity in such a manner that EUV light with a wavelength of 13.5 nm was applied to multilayer reflective films included in the respective examples 7-1 to 7-7 at an incident angle of 6.0 degrees. The measurement showed that the examples 7-1, 7-2, 7-3, 7-4, 7-5, 7-6, and 7-7 had a reflectivity of 66.9%, 66.6%, 66.5%, 66.1%, 66.7%, 66.1%, and 66.1%, respectively. The multilayer reflective films had a surface roughness of 0.13 nm rms.

Furthermore, fourteenth to sixteenth samples were prepared. The fourteenth samples had substantially the same configuration as that the examples 7-1 to 7-7 except that the fourteenth samples included no thermal diffusion-preventing films and RuMo protective films included in the respective fourteenth samples had a thickness of 0.5 to 2.5 nm and were directly formed on the respective uppermost silicon films of multilayer reflective films included in the respective fourteenth samples. The fifteenth samples had substantially the same configuration as that of the examples 7-1 to 7-4 except that thermal diffusion-preventing films included in the respective fifteenth samples had a thickness of 0.5 to 2.5 nm. The sixteenth samples had substantially the same configuration as that of the examples 7-5 to 7-7 except that thermal diffusion-preventing films included in the respective sixteenth samples had a thickness of 0.5 to 2.5 nm.

FIG. 16 shows the relationship between the thickness of the RuMo protective films of the fourteenth samples and the reflectivity of the fourteenth samples.

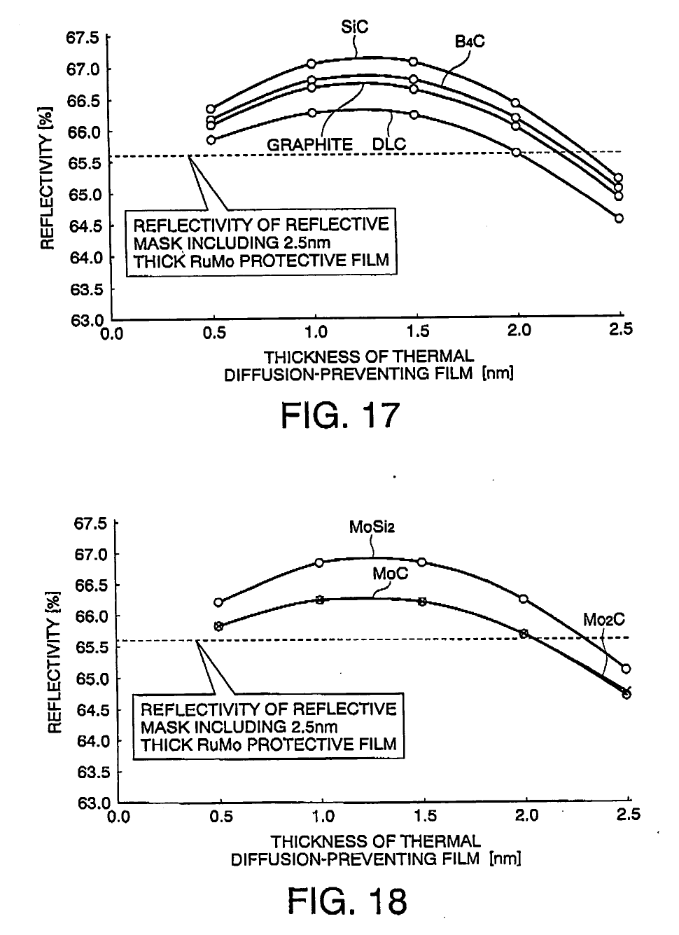

FIG. 17 shows the relationship between the thickness of the thermal diffusion-preventing films of the fifteenth samples and the reflectivity of the fifteenth samples.

FIG. 18 shows the relationship between the thickness of the thermal diffusion-preventing films of the sixteenth samples and the reflectivity of the sixteenth samples.

As illustrated in FIG. 16, the reflectivity of the fourteenth samples sharply decreases with an increase in the thickness of the RuMo protective films in the thickness range exceeding 2.0 nm. The RuMo protective films need to have a thickness of at least 2.5 nm so as to resist chemicals and/or etching. Hence, in the seventh embodiment, the thickness of the protective films of the examples 7-1 to 7-7 was set to 2.5 nm.

As illustrated in FIGS. 17 and 18, the fifteenth and sixteenth samples including the thermal diffusion-preventing films with a thickness of 0.5 to 2.0 nm have a reflectivity greater than that of the fourteenth samples that includes the RuMo protective film with a thickness of 2.5 nm. This means that the presence of the thermal diffusion-preventing films between the multilayer reflective films and the protective films leads to an increase in reflectivity. The thermal diffusion-preventing films of the examples 7-1 to 7-7 have such a thickness that the examples 7-1 to 7-7 have a maximum reflectivity. FIGS. 17 and 18 also illustrate that the fifteenth and sixteenth samples that include the thermal diffusion-preventing films with a thickness exceeding 2.0 nm have a reflectivity less than that of the fourteenth sample including the 2.5 nm thick RuMo protective film depending on the materials of the thermal diffusion-preventing films. The presence of the thermal diffusion-preventing films prevents the reflectivity of the fifteenth and sixteenth samples from being reduced due to heat treatment. However, the reflectivity of the fourteenth samples is reduced due to heat treatment by several percent because the fourteenth samples include no thermal diffusion-preventing films and diffusion layers are therefore created due to heat treatment. This means that the heat-treated fifteenth and sixteenth samples have a reflectivity greater than or equal to that of the heat-treated fourteenth sample including the 2.5 nm thick RuMo protective film.

In order to reduce the stress in the multilayer reflective films of the examples 7-1 to 7-7, the examples 7-1 to 7-7 were heat-treated at a substrate temperature of 100° C. for 15 minutes with a hot plate. Resulting examples 7-1 to 7-7 were observed by transmission electron microscopy to investigate the interfaces between the uppermost silicon films of the multilayer reflective films and the thermal diffusion-preventing films and the interfaces between the thermal diffusion-preventing films and the protective films. The observation showed that no diffusion layers were present between the above layers. There was substantially no difference in reflectivity between the heat-treated examples 7-1 to 7-7. The heat-treated examples 7-1 to 7-7 were then allowed to stand for 100 days in air. The inspection of resulting examples 7-1 to 7-7 showed that the reflectivity thereof was hardly varied.

Reflective mask blanks were prepared using the examples 7-1 to 7-7 and reflective masks having DRAM patterns were then prepared using the reflective mask blanks in the same manner as that described in the first embodiment. The reflective mask blanks and the reflective masks were measured for reflectivity using EUV light. The measurement showed that there were no serious differences between the examples 7-1 to 7-7, the reflective mask blanks, and the reflective masks, that is, the reflective mask blanks and the reflective masks had high reflectivity.

The DRAM patterns were transferred to semiconductor wafers with the pattern transfer system 50 shown in FIG. 2. The inspection of the resulting semiconductor wafers showed that the transferred patterns on the semiconductor wafers had a line width of 16 nm or less, that is, the reflective masks met 70-nm design rule requirements.

### COMPARATIVE EXAMPLE

A comparative example will now be described.

A multilayer reflective film was formed on a substrate similar to that used in the first embodiment in such a manner that silicon films with a thickness of 4.2 nm and molybdenum films with a thickness of 2.8 nm were alternately deposited on the substrate by an ion beam sputtering process. After 40 pairs of the silicon and molybdenum films were formed, a silicon film with a thickness of 4.2 nm and a ruthenium protective film with a thickness of 2.0 were deposited on the top molybdenum film in that order, whereby a seventeenth sample was prepared. The seventeenth sample was measured for reflectivity in such a manner that EUV light with a wavelength of 13.5 nm was applied to the multilayer reflective film at an incident angle of 6.0 degrees. The measurement showed that the seventeenth sample had a reflectivity of 66.6%.

The seventeenth sample was placed on a hot plate and then heat-treated at a substrate temperature of 100° C. for 15 minutes. The resulting seventeenth sample was observed by transmission electron microscopy to investigate the interface between the uppermost silicon film and the ruthenium protective film. The observation showed that diffusion layer, containing silicon and ruthenium, having a thickness of about 2.6 nm was present between these films.

A reflective mask blank was prepared using the seventeenth sample and a reflective mask having a DRAM pattern was prepared using the reflective mask blank in the same manner as that described in the first embodiment. The reflective mask was measured for reflectivity using the EUV light. The measurement showed that the reflective mask had a reflectivity of 65.4%. That is, the reflectivity of the reflective mask was 1.2% less than that of the seventeenth sample. This is probably because the diffusion layer was enlarged due to thermal causes such as the heat treatment of the seventeenth sample and the prebaking of a resist layer.

In the above embodiments, the reflectivity of the reflective mask blanks can be prevented from being reduced due to heat treatment because the thermal diffusion-preventing film formed between the uppermost silicon film and the protective film prevents the creation of the diffusion layer. Therefore, the ability of the reflective mask to reflect EUV light is substantially the same as that of the examples including the glass substrates and the multilayer reflective films, that is, the reflectivity of the reflective mask is substantially the same as that of the examples. The presence of the thermal diffusion-preventing film leads to an increase in reflectivity and is effective in preventing reflectivity from being reduced due to heat treatment, in contrast, in the comparative example, the seventeenth sample includes no thermal diffusion-preventing film and the diffusion layer is therefore created between the uppermost silicon film and the ruthenium protective film and then enlarged by heat treatment and the like; hence, the reflectivity of the reflective mask is seriously lower than that of the seventeenth sample. That is, the ability of the reflective mask to reflect EUV light is seriously lower than that of the seventeenth sample. This means that the procedure described in the comparative example is ineffective in achieving high reflectivity and the reflective mask has low reliability.

In the above embodiments, the thermal diffusion-preventing film is made of carbon, a carbon compound, a molybdenum compound, niobium, a niobium compound, zirconium, a zirconium compound, yttrium, an yttrium compound, lanthanum, a lanthanum compound, or a titanium compound. The present invention is not limited to these materials. If the thermal diffusion-preventing film is made of Mo₂Zr, Nb_{0.81}Zr_{0.19}, or the like, advantages of the present invention can be obtained.

In the above embodiments, the protective film is made of RuNb, RuZr, or RuMo. The present invention is not limited to these materials. The protective film may be made of another ruthenium compound or ruthenium.

In the above embodiments, the reflective mask blank and the reflective mask include the buffer layer formed between the protective film and the absorber film. The present invention is not limited to such a configuration. The reflective mask blank and the reflective mask need not include the buffer layer.

The present invention provides a reflective mask blank and a reflective mask that have high heat resistance and reflectivity because no diffusion layer is created in a step of forming a protective film and/or a heating step subsequent thereto. The present invention provides a semiconductor device having a fine pattern that is formed on a semiconductor substrate by lithography using such a reflective mask.

What is claimed is:

1. A reflective mask blank comprising:
a substrate;
a multilayer reflective film, formed on the substrate, for reflecting exposure light;
a protective film, formed above the multilayer reflective film, for protecting the multilayer reflective film;
an absorber film, formed on the protective film, for absorbing the exposure light;
the protective film being made of ruthenium or a ruthenium compound containing ruthenium and at least one selected from the group consisting of molybdenum, niobium, zirconium, yttrium, boron, titanium, and lanthanum; and
a thermal diffusion-preventing film formed between the multilayer reflective film and the protective film,
the thermal diffusion-preventing film being made of a material having a refractive index of greater than 0.90 and an extinction coefficient of less than −0.020.

2. The reflective mask blank according to claim 1, wherein the thermal diffusion-preventing film is made of at least one metal selected from the group consisting of molybdenum, niobium, zirconium, yttrium, titanium, and lanthanum or a compound containing at least one selected from the group consisting of molybdenum, niobium, zirconium, yttrium, titanium, and lanthanum and at least one selected from the group consisting of oxygen, boron, nitrogen, carbon, and silicon.

3. The reflective mask blank according to claim 1, wherein the thermal diffusion-preventing film is made of carbon or a compound containing carbon and at least one selected from the group consisting of oxygen, boron, nitrogen, and silicon.

4. The reflective mask blank according to claim 1, wherein the thermal diffusion-preventing film is made of a compound containing at least one selected from the group consisting of oxygen, boron, nitrogen, and silicon.

5. The reflective mask blank according to claim 1, wherein the thermal diffusion-preventing film has a thickness of 0.5 to 2.5 nm.

6. The reflective mask blank according to claim 1, further comprising a Cr based buffer layer formed between the protective film and the absorber film, which contains chromium having etching properties different from those of the absorber film.

7. The reflective mask blank according to claim 1, wherein the multilayer reflective film is heat-treated.

8. A reflective mask comprising the reflective mask blank according to any one of claims 1 to 7, wherein the absorber film is formed with a pattern to be transferred to a transfer body.

9. A method for manufacturing a semiconductor device, comprising forming a fine pattern on a semiconductor wafer by lithography using the reflective mask according to claim 8.
